(19) United States
(12) Patent Application Publication
(10) Pub. No.: US 2007/0075415 A1
(43) Pub. Date: Apr. 5, 2007

(54) Semiconductor device and semiconductor device production method

(75) Inventor: Takatoshi Osumi, Nara (JP)

Correspondence Address: STEPTOE & JOHNSON LLP, 1330 CONNECTICUT AVE., NW, WASHINGTON, DC, 20036, US

(73) Assignee: Matsushita Electric Industrial Co., Ltd., Kadoma-shi (JP)

(21) Appl. No.: 11/492,918

(22) Filed: Jul. 26, 2006

(30) Foreign Application Priority Data
Oct. 4, 2005 (JP) 2005-290606

(51) Int. Cl. H01L 23/12

(52) U.S. Cl. 257/700

(57) ABSTRACT

The present invention provides a semiconductor device in which the warp of a board is suppressed without the need for provision of a solder resist on opposite surfaces of the board and semiconductor element connection characteristics are improved by reducing stress exerted on a connection portion, and increases flexibility in assembly process.

### FIELD OF THE INVENTION

The present invention relates to a semiconductor device and a semiconductor device production method. More specifically, the present invention relates to a semiconductor device which ensures protection of an integrated circuit portion of an LSI chip, stable electrical connection between the LSI chip and an external device and higher density mounting and, particularly, relates to a semiconductor device including a semiconductor element having a multiplicity of connection terminals.

### BACKGROUND OF THE INVENTION

With recent trend toward size and weight reduction in the fields of information communication devices, office electronic devices, domestic electronic devices, measurement devices, industrial electronic devices such as assembly robots, medical electronic devices and electronic toys, there has been a heavy demand for reduction of the packaging area of semiconductor devices.

To meet the demand, BGA (ball grid array) packages and the like are employed. On the other hand, semiconductor elements to be mounted on such BGA packages are required to have a reduced chip size and a greater number of pins for higher density integration.

FIG. 8 is a sectional view illustrating the construction of a prior-art semiconductor device. As shown in FIG. 8, a board 5 includes connection electrodes 4 provided on one major surface thereof. The connection electrodes 4 are exposed from openings-formed in a solder resist 10. A semiconductor element 1 is mounted on the one major surface of the board 5 with its face down and with its connection terminals 2 respectively electrically connected to the connection electrodes 4 of the board 5. A thermosetting resin 3 intervenes between the semiconductor element 1 and the board 5 for protection of junctions of the connection terminals 2 and the connection electrodes 4.

The board 5 includes external electrodes 7 provided on the other major surface thereof. The external electrodes 7 are exposed from openings formed in a solder resist 10. The connection electrodes 4 are respectively electrically connected to the external electrodes 7 by vias 6 provided in the board 5. External terminals 8 are respectively provided on the external electrodes 7.

A publication related to the prior-art is Japanese Unexamined Patent Publication No. 2003-2182799.

In the prior art, however, the board 5 is liable to be entirely warped due to contraction of the solder resist 10 as shown in FIG. 7. This is because the thermal contraction of the solder resist 10 provided on the surfaces of the board 5 is greater than the board 5.

The warp of the board 5 causes the following problems. When the semiconductor element 1 is mounted on the board 5, not all the connection terminals 2 are brought into contact with the connection electrodes 4 of the board 5. As a result, some of the connection terminals 2 of the semiconductor element 1 are separated from the connection electrodes 4 of the board 5. This increases the possibility of poorer connection.

As the number of the junctions is increased, the board is required to have a higher planarity. However, it is difficult to provide a planarity required for the reliable electrical connection to the connection electrodes because of the warp of the board. Further, a load to be applied for connecting the connection terminals of the semiconductor element to the connection electrodes of the board is increased, as the number of the junctions is increased.

Therefore, it is difficult to design the construction of the semiconductor device to meet demands for an increased number of pins, a reduced pitch and a reduced thickness of the semiconductor element.

### DISCLOSURE OF THE INVENTION

In view of the foregoing, it is an object of the present invention to provide a semiconductor device which ensures improved mountability of a semiconductor element (more reliable and easier mounting of a semiconductor element), reduction of connection stress in the semiconductor device and suppression of deformation of junctions and, as a result, improves flexibility in designing the construction of the semiconductor device, and to provide a semiconductor device production method.

According to one aspect of the present invention to solve the aforesaid problems, there is provided a semiconductor device which comprises a board, a semiconductor element mounted on one major surface of the board with its face down, and an external terminal provided on the other major surface of the board, wherein the board includes a connection electrode provided in a recess formed in the one major surface thereof and electrically connected to a connection terminal of the semiconductor element, an external electrode provided in a recess formed in the other major surface thereof and electrically connected to the external terminal, and a via provided therein and connecting the connection electrode and the external electrode.

With this arrangement, the connection electrode and the external electrode are respectively provided in the recesses formed in the major surfaces of the board. Therefore, where the connection terminal is composed of a gold material or the like and the external terminal is composed of a solder material or the like, short circuit of adjacent connection terminals or adjacent external terminals is prevented even without provision of a solder resist.

Since there is no need to provide the solder resist on the major surfaces of the board, the board is free from thermal contraction which may otherwise occur due to the provision of the solder resist. Therefore, the planarity of the board is increased.

According to another aspect of the present invention, there is provided a semiconductor device which comprises a board, a semiconductor element mounted on one major surface of the board with its face down, and an external terminal provided on the other major surface of the board, wherein the board includes a connection electrode provided in a position of the one major surface thereof flush with the one major surface and electrically connected to a connection terminal of the semiconductor element, an external electrode provided in a recess formed in the other major surface thereof and electrically connected to the external terminal, and a via provided therein and connecting the connection electrode and the external electrode.

With this arrangement, the external electrode is provided in the recess formed in the other major surface of the board. Therefore, where the external terminal is composed of a solder material or the like, short circuit of adjacent external terminals is prevented even without provision of a solder resist.

Since there is no need to provide the solder resist on the major surfaces of the board, the board is free from thermal contraction which may otherwise occur due to the provision of the solder resist. Therefore, the planarity of the board is increased.

According to further another aspect of the present invention, there is provided a semiconductor device which comprises a board a semiconductor element mounted on one major surface of the board with its face down, and an external terminal provided on the other major surface of the board, wherein the board includes a connection electrode provided in a recess formed in the one major surface thereof and electrically connected to a connection terminal of the semiconductor element, an external electrode provided in a position of the other major surface thereof flush with the other major surface and electrically connected to the external terminal, and a via provided therein and connecting the connection electrode and the external electrode.

With this arrangement, the connection electrode is provided in the recess formed in the one major surface of the board. Therefore, where the connection terminal is composed of a gold material or the like, short circuit of adjacent connection terminals is prevented even without provision of a solder resist.

Since there is no need to provide the solder resist on the one major surface of the board on which the semiconductor element is mounted, the board is free from thermal contraction which may otherwise occur due to the provision of the solder resist. Therefore, even if the solder resist is provided on the other major surface of the board in which the external electrode is provided, the thermal contraction due to the provision of the solder resist is suppressed, thereby increasing the planarity of the board.

According to still another aspect of the present invention, there is provided a semiconductor device which comprises a board, a semiconductor element mounted on one major surface of the board with its face down, and an external terminal provided on the other major surface of the board, wherein the semiconductor element has a connection terminal formed by a wire bonding device, wherein the board includes a connection electrode provided in a recess formed in the one major surface thereof and electrically connected to the connection terminal of the semiconductor element, an external electrode provided in a recess formed in the other major surface thereof and electrically connected to the external terminal, and a via provided therein and connecting the connection electrode and the external electrode.

With this arrangement, the connection electrode and the external electrode are respectively provided in the recesses formed in the major surfaces of the board. Therefore, where the connection terminal is composed of a gold material or the like and the external terminal is composed of a solder material or the like, short circuit of adjacent connection terminals or adjacent external terminals is prevented even without provision of a solder resist.

Since there is no need to provide the solder resist on the major surfaces of the board, the board is free from thermal contraction which may otherwise occur due to the provision of the solder resist. Therefore, the planarity of the board is increased.

The connection terminal of the semiconductor element may be composed of a gold material or the like by the wire bonding device. Even if the connection terminal of the semiconductor element is offset from the center of the connection electrode, the connection terminal is effectively guided to the center of the connection electrode by the recess of the one major surface in which the connection electrode is provided.

According to further another aspect of the present invention, there is provided a semiconductor device which comprises a board, a semiconductor element mounted on one major surface of the board with its face down, and an external terminal provided on the other major surface of the board, wherein the semiconductor element has a connection terminal formed by a wire bonding device, and the board includes a connection electrode provided in a position of the one major surface thereof flush with the one major surface and electrically connected to the connection terminal of the semiconductor element, an external electrode provided in a recess formed in the other major surface thereof and electrically connected to the external terminal, and a via provided therein and connecting the connection electrode and the external electrode.

With this arrangement, the external electrode is provided in the recess formed in the other major surface of the board. Therefore, where the external terminal is composed of a solder material or the like, short circuit of adjacent external terminals is prevented even without provision of a solder resist.

Since there is no need to provide the solder resist on the major surfaces of the board, the board is free from thermal contraction which may otherwise occur due to the provision of the solder resist. Therefore, the planarity of the board is increased.

According to still another aspect of the present invention, there is provided a semiconductor device which comprises a board, a semiconductor element mounted on one major surface of the board with its face down, and an external terminal provided on the other major surface of the board, wherein the semiconductor element has a connection terminal formed by a wire bonding device, and the board includes a connection electrode provided in a recess formed in the one major surface thereof and electrically connected to the connection terminal of the semiconductor element, an external electrode provided in a position of the other major surface thereof flush with the other major surface and electrically connected to the external terminal, and a via provided therein and connecting the connection electrode and the external electrode.

With this arrangement, the connection electrode is provided in the recess formed in the one major surface of the board. Therefore, where the connection terminal is composed of a gold material or the like, short circuit of adjacent connection terminals is prevented even without provision of a solder resist.

Since there is no need to provide the solder resist on the one major surface of the board on which the semiconductor element is mounted, the board is free from thermal contraction which may otherwise occur due to the provision of the solder resist. Therefore, even if a solder resist is provided on the other major surface of the board in which the external electrode is provided, the thermal contraction due to the provision of the solder resist is suppressed, thereby increasing the planarity of the board.

The connection terminal of the semiconductor element may be composed of a gold material or the like by the wire bonding device. Even if the connection terminal of the semiconductor element is offset from the center of the connection electrode, the connection terminal is effectively guided to the center of the connection electrode by the recess of the one major surface of the board in which the connection electrode is provided.

According to further another aspect of the present invention, there is provided a semiconductor device production method which comprises the steps of: preparing a board which includes a connection electrode provided in a recess formed in one major surface thereof, an external electrode provided in a recess formed in the other major surface thereof, and a via provided therein and connecting the connection electrode and the external electrode; mounting a semiconductor element on the one major surface of the board with its face down; providing an insulative thermosetting resin between the semiconductor element and the one major surface of the board; and electrically connecting the connection terminal of the semiconductor element to the connection electrode of the board and thermally setting the thermosetting resin.

With this arrangement, the connection electrode and the external electrode are respectively provided in the recesses formed in the major surfaces of the board. Therefore, where the connection terminal is composed of the gold material or the like and the external terminal is composed of a solder material or the like, short circuit of adjacent connection terminals or adjacent external terminals is prevented even without provision of a solder resist.

Since there is no need to provide the solder resist on the major surfaces of the board, the board is free from thermal contraction which may otherwise occur due to the provision of the solder resist. Therefore, the planarity of the board is increased.

According to still another aspect of the present invention, there is provided a semiconductor device production method which comprises the steps of: preparing a board which includes a connection electrode provided in a recess formed in one major surface thereof, an external electrode provided in a recess formed in the other major surface thereof, and a via provided therein and connecting the connection electrode and the external electrode; and mounting a semiconductor element on the one major surface of the board with its face down, wherein the semiconductor element and the board are heated with in the face-down mounting step, the semiconductor element is pressed against the board with pressure while an insulative thermosetting resin provided between the semiconductor element and the one major surface of the board is being heated, the thermosetting resin is thus thermally set to bond the semiconductor element to the board, and the connecting terminal of the connection semiconductor element is electrically connected to the connection electrode of the board.

With this arrangement, the connection electrode and the external electrode are respectively provided in the recesses formed in the major surfaces of the board. Therefore, where the connection terminal is composed of a gold material or the like and the external terminal is composed of a solder material or the like, short circuit of adjacent connection terminals or adjacent external terminals is prevented even without provision of a solder resist.

Since there is no need to provide the solder resist on the major surfaces of the board, the board is free from thermal contraction which may otherwise occur due to the provision of the solder resist. Therefore, the planarity of the board is increased.

According to the present invention, the connection electrode is provided in the recess formed in the one major surface of the board, thereby eliminating the need for the provision of the solder resist. Therefore, the warp of the entire board is suppressed which may otherwise occur due to the thermal contraction of the solder resist, thereby increasing the planarity of the board. By increasing the planarity of the board, the planarity requirement for the connection terminal of the semiconductor element is alleviated. Accordingly, the process design flexibility can be increased.

Further, the deformation of the board is suppressed, so that the warp of the board and the semiconductor element after the mounting of the semiconductor element can be suppressed.

By increasing the planarity of the board, a load to be applied for correction of the warp and planarization of the board can be reduced. Therefore, a load to be applied when the semiconductor element is mounted on the board can be reduced.

The reliability of the junctions of the semiconductor element is improved by the effects described above.

### BRIEF DESCRIPTION OF THE DRAWINGS

FIG. 1 is a sectional view illustrating a semiconductor device according to Embodiment 1 of the present invention;

FIG. 2 is a sectional view illustrating a semiconductor device according to Embodiment 2 of the present invention;

FIG. 3 is a sectional view illustrating a semiconductor device according to Embodiment 3 of the present invention;

FIG. 4 is a sectional view illustrating a semiconductor device according to Embodiment 4 of the present invention;

FIG. 5 is a sectional view illustrating a semiconductor device according to Embodiment 5 of the present invention;

FIG. 6 is a sectional view illustrating a semiconductor device according to Embodiment 6 of the present invention;

FIG. 7 is a sectional view illustrating a conventional semiconductor device; and

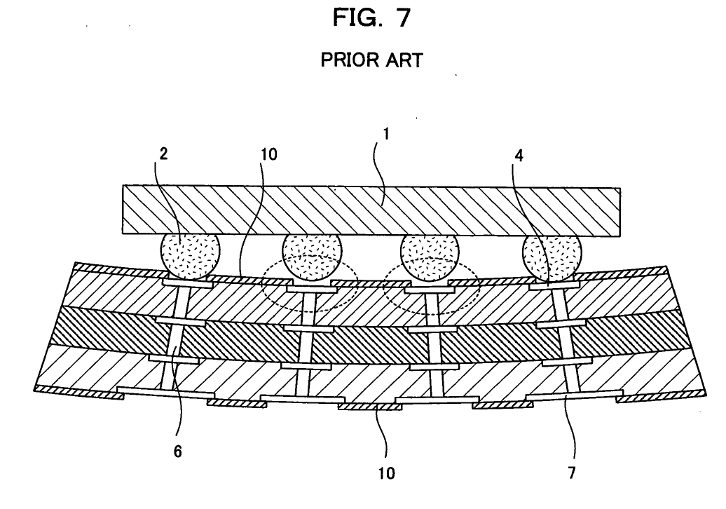

FIG. 8 is a sectional view illustrating the conventional semiconductor device.

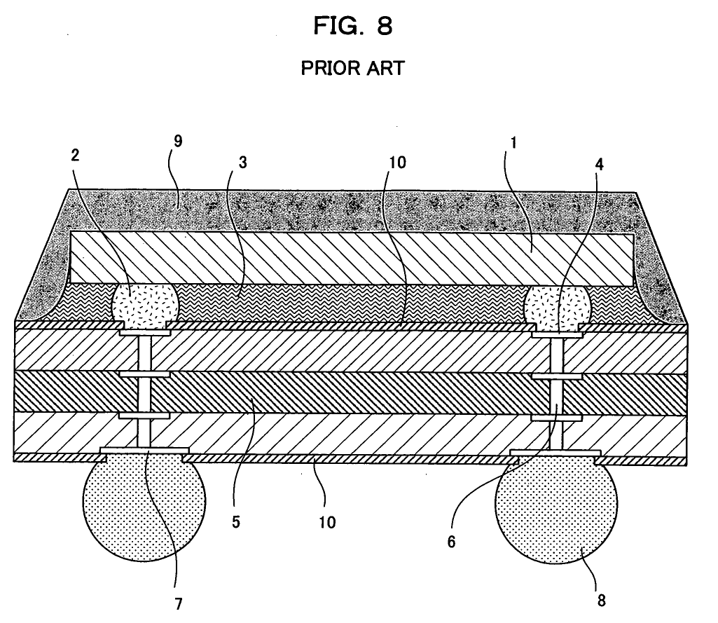

### PREFERRED EMBODIMENTS

Semiconductor devices according to embodiments of the present invention will hereinafter be described with reference to the attached drawings.

Embodiment 1

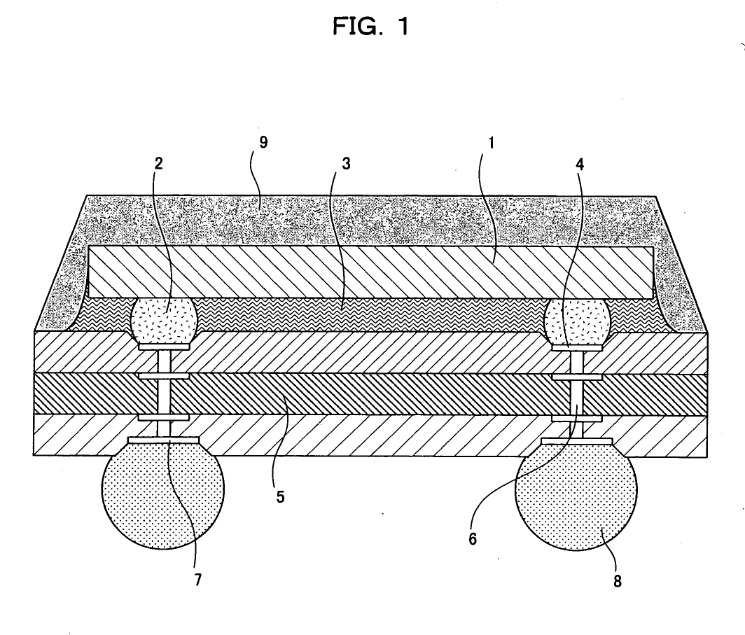

FIG. 1 is a sectional view illustrating the construction of a semiconductor device according to Embodiment 1 of the present invention. As shown in FIG. 1, no solder resist is provided on front and rear major surfaces of a board 5, and the board 5 includes connection electrodes 4 respectively provided in recesses formed in one major surface thereof, and external electrodes 7 respectively provided in recesses formed in the other major surface thereof. The board 5 further includes vias 6 provided therein and respectively electrically connecting the connection electrodes 4 to the external electrodes 7, and external terminals 8 are respectively provided on the external electrodes 7.

The depth of the connection electrodes 4 as measured from the one major surface of the board 5 to the surfaces of the connection electrodes 4 and the depth of the external electrodes 7 as measured from the other major surface of the board 5 to the surfaces of the external electrodes 7 are desirably not smaller than 10 μm, which is substantially equal to the thickness of solder resist layers which would otherwise be provided on the major surfaces.

The connection electrodes 4 and the external electrodes 7 are formed in the recesses formed in the major surfaces of the board 5 in the following manner.

Interconnection/electrode patterns are transferred onto a half-cured board 5. The interconnection/electrode patterns are thicker by at least 10 μm than a wiring circuit formed in an internal layer of the board 5.

After the board 5 is cured, the connection electrodes 4 and the external electrodes 7 are exposed in the recesses of the major surfaces of the board 5 by etching. Another method for formation of the connection electrodes 4 and the external electrodes 7 is to bury electrode/interconnection patterns in a half-cured board 5 at depths of 10 μm or more from the major surfaces of the board 5.

Next, a method of mounting a semiconductor element 1 on the board 5 will be described. Connection terminals 2 are formed on pads of the semiconductor element 1 by a plating method, a ball attaching method or a printing method. The semiconductor element 1 is mounted on the one major surface of the board 5 with its face down. At this time, the connection terminals 2 of the semiconductor element 1 are brought into abutment against the connection electrodes 4 of the board 5 with the intervention of a flux or an electrically conductive paste. In this state, the semiconductor element 1 is pressed against the board 5 by applying a pressure of not lower than 5 gf per connection electrode 4.

Then, the semiconductor element 1 and the board 5 are heated to a temperature above the melting point of the connection terminals 2, whereby the semiconductor element 1 is bonded to the board 5 with the connection terminals 2 thereof being electrically connected to the connection electrodes 4. In turn, a thermosetting resin 3 is provided between the semiconductor element 1 and the board 5, and thermally set for protection of junctions of the connection terminals 2 and the connection electrodes 4. The one major surface of the board 5 mounted with the semiconductor element 1 is sealed with a mold resin 9, whereby the semiconductor element 1, the connection terminals 2, the connection electrodes 4 and the thermosetting resin 3 are all covered with the mold resin 9.

In Embodiment 1, the material for the connection terminals 2 is a solder, but Cu, resin bumps or the like may be used for the connection terminals 2. For further improvement of connection characteristics, it is also conceivable to use a base resin which is meltable at a lower temperature. The thermosetting resin 3 may be applied or pasted on the semiconductor element 1 or the board 5 before the mounting of the semiconductor element 1, or may be inserted between the semiconductor element 1 and the board 5 after the mounting of the semiconductor element 1. Solder balls are generally used as the external terminals 8, but metal balls formed of a metal other than the solder may be used as the external terminals 8. The external terminals 8 may be in the form of lands or bumps rather than balls.

The board 5 is constituted by fiber reinforced resin layers, which are each composed of a glass fabric-epoxy laminate (GLAEPO) , an aramid nonwoven fabric or the like. Interconnections and electrodes are formed in and on the board 5 by transferring interconnection/electrode patterns onto a half-cured board 5.

The board 5 is prepared by stacking a plurality of layers (e.g., 4 to 8 layers) according to an interconnection density required by specifications. A wiring circuit to be formed in the board 5 has a thickness of about 5 μm to about 20 μm. Cu or Cu—Ni is used as a material for an internal interconnection layer. Cu—Ni—Au is used as a material for a surface interconnection.

The semiconductor element 1 generally has a thickness not smaller than 30 μm and not greater than 300 μm, and the board 5 generally has a thickness not smaller than 260 μm and not greater than 420 μm.

Where the connection terminals 2 are provided in an outer peripheral area of the semiconductor element 1, the connection terminals 2 are aligned in line or arranged in a grid array at a pitch of 60 μm to 80 μm. Where the connection terminals 2 are provided on the entire surface of the semiconductor element 1, the connection terminals 2 are arranged in a grid array at a pitch of 150 μm to 250 μm.

In the semiconductor device having the aforesaid construction, the connection electrodes 4 and the external electrodes 7 are respectively provided in the recesses formed in the major surfaces of the board 5. Therefore, short circuit of the adjacent connection terminals 2 composed of the gold material or the like or the adjacent external terminals 8 composed of the solder material or the like is prevented even without provision of the solder resist.

Since there is no need to provide the solder resist on the major surfaces of the board 5, the board is free from thermal contraction which may otherwise occur due to the provision of the solder resist. Therefore, the planarity of the board 5 is increased.

As a result, when the semiconductor element 1 is mounted on the board 5, a pressure to be applied onto the board 5 is reduced, thereby reducing the deformation of the board. Even if a higher planarity is required in a connection area in which an increased number of connection terminals 2 are provided, a load to be applied for the connection can be reduced. Further, stress acting on the connection terminals 2 is reduced, so that the mount process design for mounting the semiconductor element 1 on the board 5 can be facilitated. This leads to improvement of the reliability of the semiconductor device.

Embodiment 2

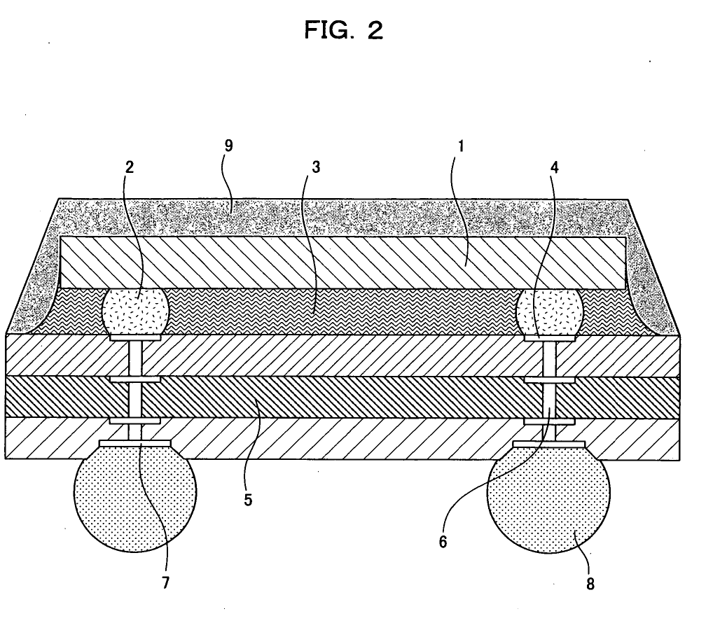

FIG. 2 is a sectional view illustrating the construction of a semiconductor device according to Embodiment 2 of the present invention. In FIG. 2, connection electrodes 4 are provided in one major surface of a board 5 with their surfaces being flush with the one major surface. External electrodes 7 are respectively provided in recesses formed in the other major surface of the board 5.

The depth of the external electrodes 7 as measured from the other major surface of the board 5 to the surfaces of the external electrodes 7 is desirably not smaller than 10 μm, which is substantially equal to the thickness of a solder resist layer which would otherwise be provided on the other major surface. The other arrangement of Embodiment 2 is the same as in Embodiment 1, and will not be described in detail.

With this arrangement, the external electrodes 7 are respectively provided in the recesses formed in the other major surface of the board 5. Therefore, where the external terminals 8 are composed of a solder material or the like, short circuit of the adjacent external terminals 8 is prevented even without provision of a solder resist.

Since there is no need to provide the solder resist on the major surfaces of the board 5, the board is free from thermal contraction which may otherwise occur due to the provision of the solder resist. Therefore, the planarity of the board 5 is increased.

As a result, when the semiconductor element 1 is mounted on the board 5, a pressure to be applied onto the board 5 is reduced, thereby reducing the deformation of the board. Even if a higher planarity is required in a connection area in which an increased number of connection terminals 2 are provided, a load to be applied for the connection can be reduced. Further, stress acting on the connection terminals 2 is reduced, so that the mount process design for mounting the semiconductor element 1 on the board 5 can be facilitated. This leads to improvement of the reliability of the semiconductor device.

Embodiment 3

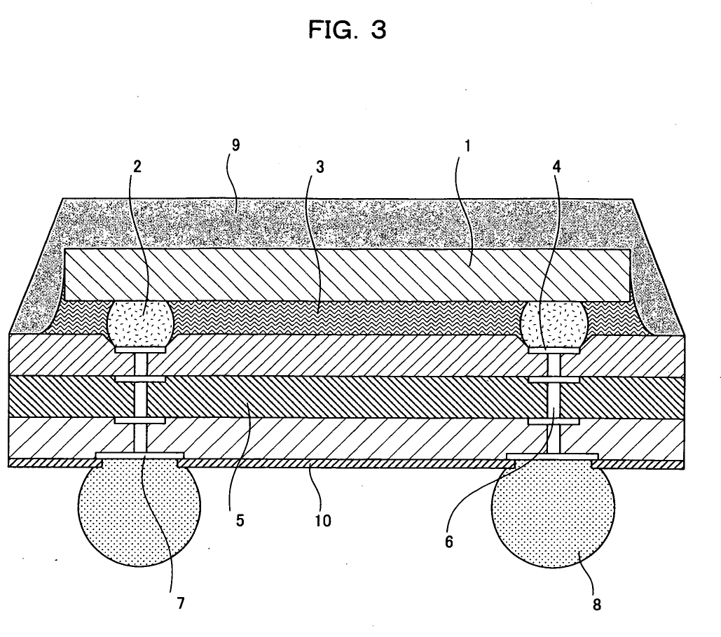

FIG. 3 is a sectional view illustrating the construction of a semiconductor device according to Embodiment 3 of the present invention. In FIG. 3, connection electrodes 4 are respectively provided in recesses formed in one major surface of a board 5. The depth of the connection electrodes 4 as measured from the one major surface of the board 5 to the surfaces of the connection electrodes 4 is desirably not smaller than 10 μm, which is substantially equal to the thickness of a solder resist layer which would otherwise be provided on the one major surface.

External electrodes 7 are provided in the other major surface of the board 5 as being exposed from openings formed in a solder resist 10 formed on the other major surface of the board 5. The surfaces of the external electrodes 7 are flush with the other major surface of the board 5. The other arrangement of Embodiment 3 is the same as in Embodiment 1, and will not be described in detail.

In the semiconductor device having the aforesaid construction, the connection electrodes 4 are respectively provided in the recesses formed in the one major surface of the board 5. Therefore, where the connection terminals 2 are composed of a gold material or the like, short circuit of the adjacent connection terminals 2 is prevented even without provision of a solder resist on the one major surface.

Since there is no need to provide the solder resist on the one major surface of the board 5, the board is free from thermal contraction which may otherwise occur due to the provision of the solder resist. Therefore, the planarity of the board 5 is increased. Even if the solder resist 10 is provided on the other major surface on which the external electrodes 7 are provided, the thermal contraction due to the provision of the solder resist is suppressed, increasing the planarity of the board 5.

As a result, when the semiconductor element 1 is mounted on the board 5, a pressure to be applied onto the board 5 is reduced, thereby reducing the deformation of the board. Even if a higher planarity is required in a connection area in which an increased number of connection terminals 2 are provided, a load to be applied for the connection can be reduced. Further, stress acting on the connection terminals 2 is reduced, so that the mount process design for mounting the semiconductor element 1 on the board 5 can be facilitated. This leads to improvement of the reliability of the semiconductor device.

Embodiment 4

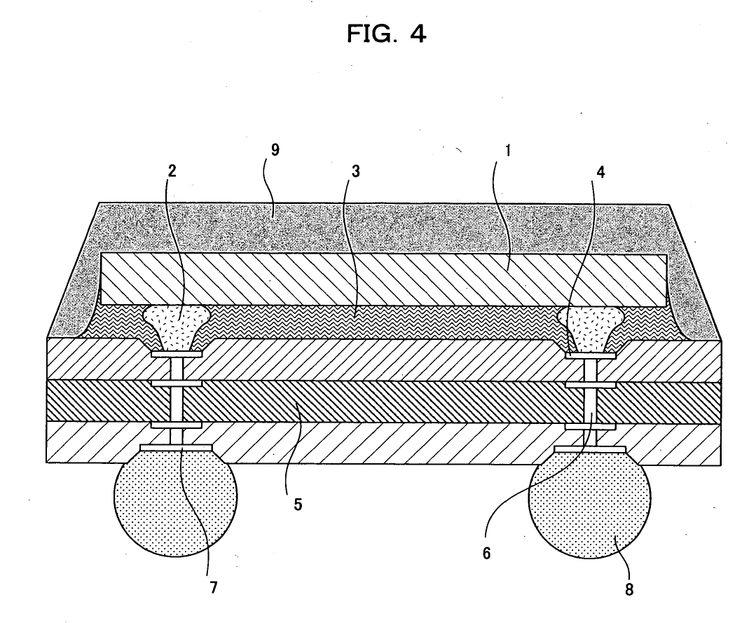

FIG. 4 is a sectional view illustrating the construction of a semiconductor device according to Embodiment 4 of the present invention. As shown in FIG. 4, a board 5 includes connection electrodes 4 provided in recesses formed in one major surface thereof, and external electrodes 7 provided in recesses formed in the other major surface thereof.

A semiconductor element 1 includes connection terminals 2 respectively formed on pads by a wire bonding device. The connection terminals 2 each have a tapered distal portion.

The semiconductor element 1 is mounted on the one major surface of the board 5 with its face down, and pressed against the board 5 by applying a pressure of not lower than 20 gf per connection electrode 4 with heating. Then, a thermosetting resin 3 provided between the semiconductor element 1 and the board 5 is thermally set, while the warp of the board 5 is corrected by the pressure. Thus, the semiconductor element 1 is bonded to the board 5 with the connection terminals 2 being electrically connected to the connection electrodes 4.

Another method for the mounting of the semiconductor element 1 is as follows. The semiconductor element 1 is mounted on the one major surface of the board 5 formed with the connection electrodes 4 with its face down. At this time, the connection terminals 2 of the semiconductor element 1 are brought into abutment against the connection electrodes 4 of the board 5 with the intervention of a flux or an electrically conductive paste.

Then, the semiconductor element 1 is pressed against the board 5 by applying a pressure of not lower than 5 gf per connection electrode 4. In turn, the semiconductor element 1 and the board 5 are heated to a temperature above the melting point of a solder paste or to the curing temperature of the electrically conductive paste, whereby the semiconductor element 1 is bonded to the board 5 with the connection terminals 2 being electrically connected to the connection electrodes 4. Then, a thermosetting resin 3 provided between the semiconductor element 1 and the board 5 is thermally set for protection of junctions of the connection terminals 2 and the connection electrodes 4.

In Embodiment 4, the connection terminals 2 are composed of gold, but may be composed of Ag, Cu or the like. For further improvement of connection characteristics, it is also conceivable to use a base resin which is meltable at a lower temperature. The thermosetting resin 3 may be applied or pasted on the semiconductor element 1 or the board 5 before the mounting of the semiconductor element 1, or may be inserted between the semiconductor element 1 and the board 5 after the mounting of the semiconductor element 1. The other arrangement of Embodiment 4 is the same as in Embodiment 1, and will not be described in detail.

In the semiconductor device having the aforesaid construction, the connection electrodes 4 and the external electrodes 7 are respectively provided in the recesses formed in the major surfaces of the board 5. Therefore, where the connection terminals 2 are composed of a gold material or the like and the external terminals 8 are composed of a solder material or the like, short circuit of the adjacent connection terminals 2 or the adjacent external terminals 8 is prevented even without provision of a solder resist on the major surfaces.

Even if the connection terminals 2 of the semiconductor element 1 formed of the gold material or the like by the wire bonding device are offset from the centers of the connection electrodes 4, the connection terminals 2 are effectively guided to the centers of the connection electrodes 4 by the recesses of the one major surface in which the connection electrodes 4 are provided. Therefore, short circuit of the adjacent connection terminals 2 composed of the gold material or the like is prevented even without the provision of the solder resist on the one major surface.

Since there is no need to provide the solder resist on the major surfaces of the board 5, the board is free from thermal contraction which may otherwise occur due to the provision of the solder resist. Therefore, the planarity of the board 5 is increased.

As a result, when the semiconductor element 1 is mounted on the board 5, a pressure to be applied onto the board 5 is reduced, thereby reducing the deformation of the board. Even if a higher planarity is required in a connection area in which an increased number of connection terminals 2 are provided, a load to be applied for the connection can be reduced. Further, stress acting on the connection terminals 2 is reduced, so that the mount process design for mounting the semiconductor element 1 on the board 5 can be facilitated. This leads to improvement of the reliability of the semiconductor device.

Embodiment 5

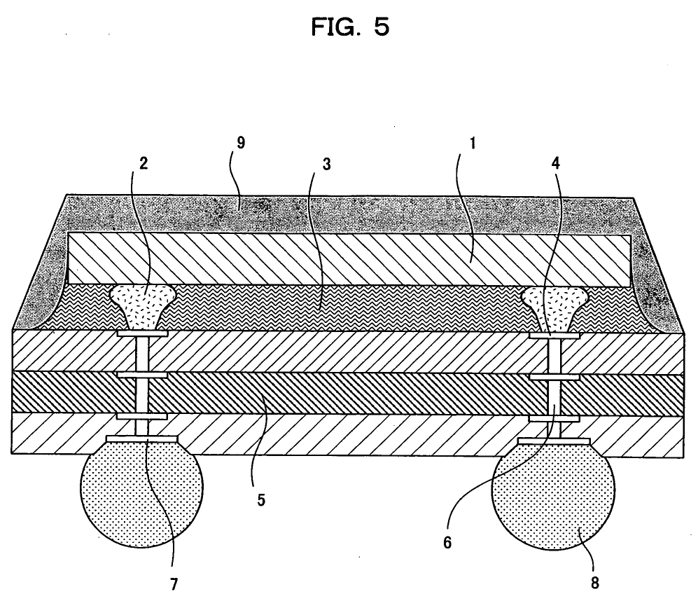

FIG. 5 is a sectional view illustrating the construction of a semiconductor device according to Embodiment 5 of the present invention. As shown in FIG. 5, connection electrodes 4 are provided in one major surface of a board 5 with their surfaces being flush with the one major surface, and external electrodes 7 are provided in recesses formed in the other major surface of the board 5. The depth of the external electrodes 7 as measured from the other major surface of the board 5 to the surfaces of the external electrodes 7 is desirably not smaller than 10 μm, which is substantially equal to the thickness of a solder resist layer which would otherwise be provided on the other major surface.

The connection electrodes 4 are respectively electrically connected to the external electrodes 7 by vias 6 provided in the board 5, and external terminals 8 are respectively provided on the external electrodes 7. The semiconductor element 1 includes connection terminals 2 formed on pads by a wire bonding device. The connection terminals 2 each have a tapered distal portion. The other arrangement of Embodiment 5 and the method for the mounting of the semiconductor element 1 are the same as in Embodiment 4, and will not be described in detail.

With this arrangement, the external electrodes 7 are respectively provided in the recesses formed in the other major surface of the board 5. Therefore, where the external terminals 8 are composed of a solder material or the like, short circuit of the adjacent external terminals 8 is prevented even without provision of a solder resist.

Since there is no need to provide the solder resist on the other major surface of the board 5, the board is free from thermal contraction which may otherwise occur due to the provision of the solder resist. Therefore, the planarity of the board 5 is increased.

As a result, when the semiconductor element 1 is mounted on the board 5, a pressure to be applied onto the board 5 is reduced, thereby reducing the deformation of the board. Even if a higher planarity is required in a connection area in which an increased number of connection terminals 2 are provided, a load to be applied for the connection can be reduced. Further, stress acting on the connection terminals 2 is reduced, so that the mount process design for mounting the semiconductor element 1 on the board 5 can be facilitated. This leads to improvement of the reliability of the semiconductor device.

Embodiment 6

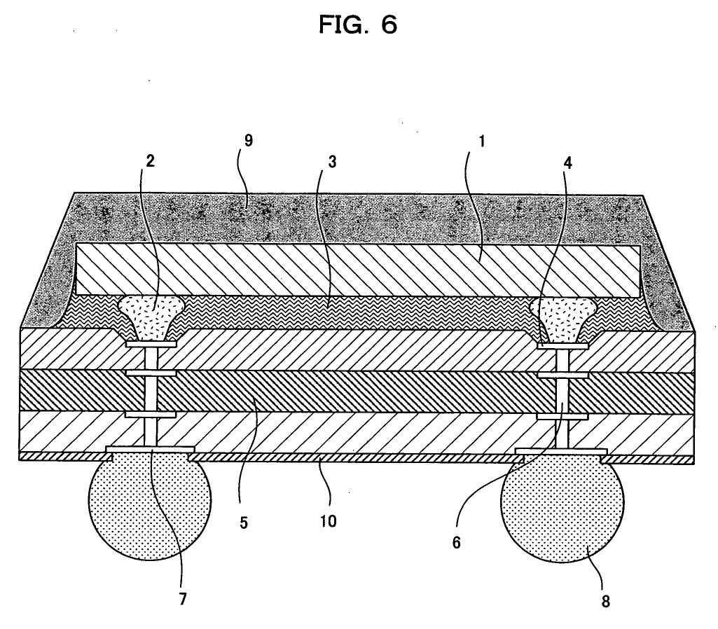

FIG. 6 is a sectional view illustrating the construction of a semiconductor device according to Embodiment 6 of the present invention. In FIG. 6, connection electrodes 4 are respectively provided in recesses formed in one major surface of a board 5. The depth of the connection electrodes 4 as measured from the one major surface of the board 5 to the surfaces of the connection electrodes 4 is desirably not smaller than 10 μm, which is substantially equal to the thickness of a solder resist layer which would otherwise be provided on the one major surface.

External electrodes 7 are provided in the other major surface of the board 5 as being exposed from openings formed in a solder resist 10 formed on the other major surface of the board 5. The surfaces of the external electrodes 7 are flush with the other major surface of the board 5. The other arrangement of Embodiment 6 is the same as in Embodiment 4, and will not be described in detail.

In the semiconductor device having the aforesaid construction, the connection electrodes 4 are respectively provided in the recesses formed in the one major surface of the board 5. Therefore, where the connection terminals 2 are composed of a gold material or the like, short circuit of the adjacent connection terminals 2 is prevented even without provision of a solder resist.

The connection terminals 2 of the semiconductor element 1 may be composed of a gold material or the like by a wire bonding device. Even if the connection terminals 2 of the semiconductor element 1 are offset from the centers of the connection electrodes 4, the connection terminals 2 are effectively guided to the centers of the connection electrodes 4 by the recesses of the one major surface of the board 5 in which the connection electrodes 4 are provided. Therefore, short circuit of the adjacent connection terminals 2 composed of the gold material or the like is prevented even without the provision of the solder resist on the one major surface.

Since there is no need to provide the solder resist on the one major surface of the board 5, the board is substantially free from thermal contraction which may otherwise occur due to the provision of the solder resist. Therefore, the planarity of the board 5 is increased.

As a result, when the semiconductor element 1 is mounted on the board 5, a pressure to be applied onto the board 5 is reduced, thereby reducing the deformation of the board. Even if a higher planarity is required in a connection area in which an increased number of connection terminals 2 are provided, a load to be applied for the connection can be reduced. Further, stress acting on the connection terminals 2 is reduced, so that the mount process design for mounting the semiconductor element 1 on the board 5 can be facilitated. This leads to improvement of the reliability of the semiconductor device.

The present invention provides the semiconductor devices which ensure protection of an integrated circuit portion of an LSI chip, stable electrical connection between the LSI chip and an external device and higher density mounting. The present invention is effectively applied to semiconductor devices in which semiconductor elements of higher power consumption are mounted, and improves the reliability of semiconductor devices for use in information communication devices, office electronic devices, domestic electronic devices, measurement devices, industrial electronic devices such as assembly robots, medical electronic devices and electronic toys.

What is claimed is:

1. A semiconductor device comprising:
a board;
a semiconductor element mounted on one major surface of the board with its face down; and
an external terminal provided on the other major surface of the board, wherein the board includes a connection electrode provided in a recess formed in the one major surface thereof and electrically connected to a connection terminal of the semiconductor element, an external electrode provided in a recess formed in the other major surface thereof and electrically connected to the external terminal, and a via provided therein and connecting the connection electrode and the external electrode.

2. A semiconductor device comprising:
a board;
a semiconductor element mounted on one major surface of the board with its face down; and
an external terminal provided on the other major surface of the board, wherein
the board includes a connection electrode provided in a position of the one major surface flush with the one major surface thereof and electrically connected to a connection terminal of the semiconductor element, an external electrode provided in a recess formed in the other major surface thereof and electrically connected to the external terminal, and a via provided therein and connecting the connection electrode and the external electrode.

3. A semiconductor device comprising:
a board;
a semiconductor element mounted on one major surface of the board with its face down; and
an external terminal provided on the other major surface of the board, wherein
the board includes a connection electrode provided in a recess formed in the one major surface thereof and electrically connected to a connection terminal of the semiconductor element, an external electrode provided in a position of the other major surface thereof flush with the other major surface and electrically connected to the external terminal, and a via provided therein and connecting the connection electrode and the external electrode.

4. A semiconductor device comprising:
a board;
a semiconductor element mounted on one major surface of the board with its face down; and
an external terminal provided on the other major surface of the board, wherein
the semiconductor element has a connection terminal formed by a wire bonding device, and
the board includes a connection electrode provided in a recess formed in the one major surface thereof and electrically connected to the connection terminal of the semiconductor element, an external electrode provided in a recess formed in the other major surface thereof and electrically connected to the external terminal, and a via provided therein and connecting the connection electrode and the external electrode.

5. A semiconductor device comprising:
a board;
a semiconductor element mounted on one major surface of the board with its face down; and
an external terminal provided on the other major surface of the board, wherein
the semiconductor element has a connection terminal formed by a wire bonding device, and
the board includes a connection electrode provided in a position of the one major surface thereof flush with the one major surface and electrically connected to the connection terminal of the semiconductor element, an external electrode provided in a recess formed in the other major surface thereof and electrically connected to the external terminal, and a via provided therein and connecting the connection electrode and the external electrode.

6. A semiconductor device comprising:
a board;
a semiconductor element mounted on one major surface of the board with its face down; and
an external terminal provided on the other major surface of the board, wherein
the semiconductor element has a connection terminal formed by a wire bonding device, and
the board includes a connection electrode provided in a recess formed in the one major surface thereof and electrically connected to the connection terminal of the semiconductor element, an external electrode provided in a position of the other major surface thereof flush with the other major surface and electrically connected to the external terminal, and a via provided therein and connecting the connection electrode and the external electrode.

7. A semiconductor device production method, comprising the steps of:
preparing a board including a connection electrode provided in a recess formed in one major surface thereof, an external electrode provided in a recess formed in the other major surface thereof, and a via provided therein and connecting the connection electrode and the external electrode;
mounting a semiconductor element on the one major surface of the board with its face down;
providing an insulative thermosetting resin between the semiconductor element and the one major surface of the board; and
electrically connecting the connection terminal of the semiconductor element to the connection electrode of the board and thermally setting the thermosetting resin.

8. A semiconductor device production method comprising the steps of:
preparing a board including a connection electrode provided in a recess formed in one major surface thereof, an external electrode provided in a recess formed in the other major surface thereof, and a via provided therein and connecting the connection electrode and the external electrode; and
mounting a semiconductor element on the one major surface of the board with its face down, wherein in the face-down mounting step, the semiconductor element is pressed against the board with pressure while an insulative thermosetting resin provided between the semiconductor element and the one major surface of the board is being heated, the thermosetting resin is thus thermally set to bond the semiconductor element to the board, and the connection terminal of the semiconductor element is electrically connected to the connection electrode of the board.
